(19) United States
(12) Patent Application Publication
(10) Pub. No.: US 2007/0057256 A1
(43) Pub. Date: Mar. 15, 2007

(54) ELEMENT FORMING SUBSTRATE, ACTIVE MATRIX SUBSTRATE, AND METHOD OF MANUFACTURING THE SAME

(76) Inventors: Yujiro Hara, Yokohama-shi (JP); Yutaka Onozuka, Yokohama-shi (JP); Keiji Sugi, Chigasaki-shi (JP); Masahiko Akiyama, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/469,709

(22) Filed: Sep. 1, 2006

(30) Foreign Application Priority Data
Sep. 9, 2005 (JP) 2005-262840

(51) Int. Cl. H01L 29/04

(52) U.S. Cl. 257/59

(57) ABSTRACT

An element forming substrate includes a substrate and a plurality of elements which are arranged in a matrix form on the substrate. Each of the elements includes a thin film transistor and contact pads connected to the transistor, and has peripheral sides separated from adjacent elements in a plane of the substrate. A channel direction of the transistor is inclined relative to the peripheral sides of the elements.

### CROSS-REFERENCE TO RELATED APPLICATIONS

This application is based upon and claims the benefit of priority from prior Japanese Patent Application No. 2005-262840, filed Sep. 9, 2005, the entire contents of which are incorporated herein by reference.

### BACKGROUND OF THE INVENTION

1. Field of the Invention

The present invention relates to an element forming substrate, an active matrix substrate, and a method of manufacturing the same.

2. Description of the Related Art

Because liquid crystal displays and organic EL displays are flat screen types of low power consumption, and capable of displaying in colors, these displays are used as display units in notebook personal computers, monitors, televisions, mobile telephones, and the like. In liquid crystal displays and organic EL displays required to display at higher definition, an active matrix substrate is used which is configured such that thin film transistors (TFTs) having amorphous silicon (hereinafter referred to as amorphous-Si) or polycrystalline silicon (hereinafter referred to as poly-Si) serving as an active layer are arranged in a matrix form on a glass substrate. As regards an active matrix substrate, there are demands for a large screen, reduced weight, flattening, reduction in manufacturing cost, and the like, along with demands for lower power consumption, higher definition, etc.

In order to satisfy these demands, a method of manufacturing an element transcribing type of active matrix element has been conventionally proposed (for example, in JP-A 2001-7340 (KOKAI). In the invention disclosed in JP-A 2001-7340 (KOKAI), a plurality of elements each including an amorphous-Si TFT are formed on an element forming substrate, the elements are separated in a plane of the substrate, and then, transcribed onto a transcription destination substrate, and moreover, wirings or the like are formed to manufacture an active matrix element.

A conventional method of manufacturing an element transcribing type active matrix element will be described hereinafter.

First, as shown in FIG. 41, a plurality of elements 1 are formed in a matrix form on an element forming substrate 51 made of glass. As shown in FIGS. 42 and 43, the TFT 2 includes a gate electrode 3, a source electrode 4, a drain electrode 5, and a channel portion 6 formed of a semiconductor layer. As shown in FIG. 42, the gate electrode 3, the source electrode 4, and the drain electrode 5 take connections to wirings or a pixel electrode to be described later, and thus, the gate electrode 3, the source electrode 4, and the drain electrode 5 are connected to a gate electrode contact pad 7, a source electrode contact pad 8, and a drain electrode contact pad 9, respectively.

Next, the elements 1 adjacent to one another are separated in a plane of the element forming substrate 51. In the separation, peripheral sides 10 of the element 1 form a rectangle, and a channel direction defined as a direction in which electric current flows in the channel portion 6 of the TFT 2 is formed to coincide with a direction of the peripheral side 10 of the element 1.

Subsequently, as shown in FIG. 44, the elements 1 on the element forming substrate 51 are simultaneously transcribed onto the transcription destination substrate 31 so that the elements 1 are periodically arranged on a transcription destination substrate 31. Further, as shown in FIG. 45, wirings including gate lines 32 and signal lines 33 are formed on the transcription destination substrate 31. At the same time, as shown in FIGS. 46 and 47, each of the gate lines 32 is connected to the gate electrode contact pads 7 in the elements 1 which are laterally on the same column, and each of the signal lines 33 is connected to the source electrode contact pads 8 in the elements 1 which are vertically on the same column. The gate lines 32 and signal lines 33 are isolated by an insulating film or the like, not shown.

Moreover, as shown in FIGS. 46 and 47, pixel electrodes 35 are formed to be connected to the drain electrode contact pads 9, so that an element transcribing type active matrix element can be obtained.

Here, there are two requirements for the wirings and the pixel electrodes. One is that the gate lines 32, the signal lines 33, and the pixel electrodes 35 are favorably connected to the source electrode contact pads 8, the drain electrode contact pads 9, and the drain electrode contact pads 9, respectively, and are not short-circuited with the other electrode contact pads. The other is that the wirings, the pixel electrodes, and circuit portions having the same electric potential as those are not overlapped with the channel portions 6 of the TFTs 2, so that parasitic capacitance and malfunctions do not occur.

These requirements must be satisfied even if there is deformation or misalignment in a process of forming the active matrix substrate. As causes of deformation or misalignment, there are displacement at the time of transcribing the elements 1 on the element forming substrate 51 onto the transcription destination substrate 31, misalignment due to a difference in the deformation amounts of the element forming substrate 51 and the transcription destination substrate 31, variations in side etching at the time of forming patterns of the electrode contact pads, contact holes, wirings and the like, displacement of an exposure mask at the time of patterning, and the like. Therefore, it is necessary for the gate electrode contact pads 7, the source electrode contact pads 8, and the drain electrode contact pads 9 to be made to have sizes of about 10 to 20 μm square.

Further, in order to improve the efficiency in the use of the element forming substrate 51, it is preferable that the pitch of the elements 1 on the element forming substrate 51 is small. The channel portion 6 of the TFT 2 is required to have a channel length that is determined on the basis of a length of a gate electrode in a direction between the source electrode and the drain electrode, of about 10 μm, and a channel width of about 10 to 30 μm in a direction perpendicular to the channel length.

When the TFT 2 with a channel length of 10 μm and a channel width of 25 μm, and the gate electrode contact pad 7, the source electrode contact pad 8, and the drain electrode contact pad 9 whose sizes are respectively 20 μm square are arranged in the element 1, the size of the element 1 can be reduced to about 60 μm square by forming the TFT 2, and the gate electrode contact pad 7, the source electrode contact pad 8, and the drain electrode contact pad 9 in close proximity to the element peripheral sides 10, as shown in FIG. 42.

Further, in manufacturing the an active matrix substrate, the TFTs 2 requiring a high-temperature process are formed at high density in advance on the element forming substrate 51 having a high heat resistance, and the TFTs 2 are transcribed onto the transcription destination substrate 31 so as to be thinned out. Consequently, it is possible to reduce the higher cost for forming the TFTs 2 than the cost for forming the wirings, and therefore, the active matrix substrate can be prepared at a lower cost. In addition, it is possible to make the active matrix substrate flexible by using a plastic film having a low heat resistance as the transcription destination substrate 31.

On the other hand, as shown in FIG. 42, the channel portion 6 of the TFT 2 is formed in the vicinity of the peripheral side 10 of the element 1, by setting a channel direction of the TFT 2 formed in the element 1 to be parallel to one side of the peripheral sides 10 of the rectangle, forming the source electrode contact pad 8 to be adjacent to the source electrode 4 along the channel direction of the TFT 2, forming the drain electrode contact pad 9 to be adjacent to the drain electrode 5, and forming the gate electrode contact pad 7 to be adjacent to the gate electrode 3 in a direction perpendicular to the channel direction of the TFT 2. In such a case, for example, there is the problem that, in a process in which the elements 1 formed on the element forming substrate 51 are separated by etching or the like in a plane of the substrate, a portion of the channel portion 6 in which source-drain current flows is easily damaged by side-etching, permeation of etchant, etc. from the position of α in FIG. 42.

In order to solve such a problem, the TFT 2 with a channel width of 25 μm may be arranged at a position distant from the peripheral sides 10 of the element 1, and the gate electrode contact pad 7, the source electrode contact pad 8, and the drain electrode contact pad 9 all having sizes of 20 μm square may be arranged so as to be connected to the gate electrode 3, the source electrode 4, and the drain electrode 5 of the TFT 2, respectively. In this case, these members are arranged as shown in, for example, FIG. 48, so that in a process in which the adjacent elements formed on the element forming substrate 51 are separated in a plane of the substrate, the channel portion 6 of the TFT 2 is made more resistant to damage caused by side-etching, permeation of etchant, etc. On the other hand, the problem is brought about that a size of the element 1 becomes about 60 μm×90 μm, which is about 1.5 times larger than the size of the element 1 in the case shown in FIG. 42, and the density in which the elements 1 are formed on the element forming substrate 51 is reduced, accordingly.

Moreover, it is possible to display while curving the substrate in a display using a flexible substrate such as a plastic film as the transcription destination substrate 31. However, a warp occurs in a film formed on the substrate when the substrate is curved. The degree of a warping is inversely proportional to a radius of curvature at the time of curving. It is known that a transfer property of the TFT 2 varies when a warp occurs in the channel portion 6 of the TFT 2, which leads to deterioration in image quality due to a decrease in contrast or uneven display in a plane. Further, when it is stretched in the channel direction, a crack is brought about in a direction perpendicular to the channel, which increases electrical resistance in the TFT.

Depending on a display, in some cases, a usage in which the transcription destination substrate 31 is curved only in a vertical or lateral direction is taken as shown in FIGS. 49 and 50. In this case, a display region 52 of the transcription destination substrate 31 is curved only in a vertical or lateral direction, as well. For example, in the case where the elements 1 are arranged in a matrix form in the display region 52 such that a channel direction of the TFTs 2 is made to be a lateral direction as shown in FIG. 46, a warp occurs along the channel direction of the TFTs 2 when the transcription destination substrate 31 is curved in the direction shown in FIG. 50. Further, in the case where the elements 1 are arranged in a matrix form in the display region 52 such that a channel direction of the TFTs 2 is made to be a vertical direction, a warp occurs along the channel direction of the TFTs 2 when the transcription destination substrate 31 is curved in the direction shown in FIG. 49. In this way, in the case where the elements are arranged such that a channel direction of the TFT 2 coincides with a direction of one side of the peripheral sides 10 of the element 1, there occurs the problem that, when the display region is curved in a vertical or lateral direction, a warp in a channel direction brought about in the channel portion 6 of the TFT 2 is made largest depending on a direction of curving, which leads to deterioration in picture quality or cracks.

As described above, in the method described in JP-A 2001-7340 (KOKAI), there is the problem that, in a process that adjacent elements on an element forming substrate are separated in a plane of the substrate by etching or the like, channel portions are easily damaged by side etching, permeation of etchant, etc.

Further, there occurs the problem that, when a TFT is arranged at a position distant from a peripheral sides of an element in order to avoid damage in a channel portion by side etching, permeation of etchant, etc., a size of the element is made larger, and the density in which the elements are formed on an element forming substrate is reduced.

Moreover, in an active matrix substrate in which it is curved only in a vertical or lateral direction in usage, when the elements are arranged such that a channel direction of TFTs coincides with a direction of one side of the peripheral sides of an element, there occurs the problem that, in the case where a display region is curved in a vertical or lateral direction, a warp in the channel direction occurring in the channel portion 6 of the TFT is made largest, which leads to deterioration in image quality or cracks.

### BRIEF SUMMARY OF THE INVENTION

According to an aspect of the present invention, there is provided an element forming substrate comprising:

a substrate; and

a plurality of elements which are arranged in a matrix form on the substrate, each of the elements including a thin film transistor and contact pads connected to the transistor, and having peripheral sides separated from adjacent elements in a plane of the substrate, and a channel direction of the transistor being inclined relative to the peripheral sides of the elements.

According to another aspect of the present invention, there is provided an element forming substrate comprising:

a substrate; and

a plurality of elements which are arranged in a matrix form on the substrate, each of the elements including a thin film transistors and contact pads connected to the thin film transistor, a channel direction of the transistor is inclined relative to an array direction of the elements.

According to a further aspect of the present invention, there is provided an active matrix substrate comprising:

a substrate;

a plurality of wirings including gate lines and signal lines which are arranged in a matrix form on the substrate;

a plurality of elements which are arranged in intersection portions of the wirings, each of the elements including a thin film transistor and contact pads connected to the transistor, and having peripheral sides separated from adjacent elements in a plane of the substrate, a channel direction of the thin film transistor is inclined relative to a wiring direction of the wirings.

According to a further aspect of the present invention, there is provided an active matrix substrate comprising:

a substrate;

a plurality of wirings including gate lines and signal lines which are arranged in a matrix form on the substrate; and

a plurality of elements which are arranged in intersection portions of the wirings, each of the elements including a thin film transistor and contact pads connected to the transistor, the transistor comprising a gate electrode, a semiconductor layer formed on the gate electrode via an insulating film, and a source electrode and a drain electrode which are connected to the semiconductor layer, the contact pads comprising a gate electrode contact pad connected to the gate electrode, a source electrode contact pad connected to the source electrode, and a drain electrode contact pad connected to the drain electrode, each of the elements having peripheral sides separated from adjacent elements in a plane of the substrate, the source electrode contact pad and the drain electrode contact pad being arranged, among four interior corners including a first interior corner, a second interior corner, a third interior corner and a fourth interior corner configured by the peripheral sides of the element, at the first and second interior corners opposite to each other, the gate electrode contact pad being arranged at the third interior corner which is opposite to the fourth interior corner, and the semiconductor layer being not formed at the fourth interior corner.

According to a further aspect of the present invention, there is provided a method of manufacturing an active matrix substrate, comprising:

forming a plurality of elements in a matrix form on an element forming substrate, each of the elements including a thin film transistor and contact pads connected to the transistor;

separating the elements from each other to form peripheral sides of the elements; and

transcribing the separated elements onto a transcription destination substrate;

wherein, when the elements are formed, a channel direction of the thin film transistor is inclined relative to the peripheral sides of the elements.

### BRIEF DESCRIPTION OF THE SEVERAL VIEWS OF THE DRAWING

FIG. 1 is a cross-sectional view for explaining a method of manufacturing an element forming substrate according to a first embodiment;

FIG. 2 is a plan view for explaining the manufacturing method according to the first embodiment;

FIG. 3 is a cross-sectional view taken along direction III-III of the element forming substrate shown in FIG. 2;

FIG. 4 is a cross-sectional view for explaining the manufacturing method according to the first embodiment;

FIG. 5 is a plan view for explaining the manufacturing method according to the first embodiment;

FIG. 6 is a cross-sectional view taken along direction VI-VI of the element forming substrate shown in FIG. 5;

FIG. 7 is a plan view for explaining the manufacturing method according to the first embodiment;

FIG. 8 is a cross-sectional view taken along direction VIII-VIII of the element forming substrate shown in FIG. 7;

FIG. 9 is a plan view for explaining the manufacturing method according to the first embodiment;

FIG. 10 is a cross-sectional view taken along direction X-X of the element forming substrate shown in FIG. 19;

FIG. 11 is a plan view for explaining the manufacturing method according to the first embodiment;

FIG. 12 is a cross-sectional view for explaining a method for transcription from the element forming substrate to an intermediate transcription substrate according to the first embodiment;

FIG. 13 is a cross-sectional view for explaining the transcription method according to the first embodiment;

FIG. 14 is a cross-sectional view for explaining the transcription method according to the first embodiment;

FIG. 15 is a cross-sectional view for explaining the transcription method according to the first embodiment;

FIG. 16 is a cross-sectional view for explaining the transcription method according to the first embodiment;

FIG. 17 is a cross-sectional view for explaining the transcription method according to the first embodiment;

FIG. 18 is a plan view for explaining a method of manufacturing an active matrix substrate according to the first embodiment;

FIG. 19 is a plan view for explaining the manufacturing method of the active matrix substrate according to the first embodiment;

FIG. 20 is a cross-sectional view taken along a line XX-XX of the active matrix substrate shown in FIG. 19;

FIG. 21 is a plan view for explaining the manufacturing method of the active matrix substrate according to the first embodiment;

FIG. 22 is a cross-sectional view taken along a line XXII-XXII of the active matrix substrate shown in FIG. 21;

FIG. 23 is a plan view for explaining the manufacturing method of the active matrix substrate according to the first embodiment;

FIG. 24 is a cross-sectional view for explaining the manufacturing method of the active matrix substrate according to the first embodiment;

FIG. 25 is a plan view for explaining the manufacturing method of the active matrix substrate according to the first embodiment;

FIG. 26 is a plan view for explaining the manufacturing method of the active matrix substrate according to the first embodiment;

FIG. 27 is a cross-sectional view taken along a line XXVII-XXVII of the active matrix substrate shown in FIG. 26;

FIG. 28 is a plan view for explaining the manufacturing method of manufacturing the active matrix substrate according to the first embodiment;

FIG. 29 is a plan view for explaining the manufacturing method of the active matrix substrate according to the first embodiment;

FIG. 30 is a cross-sectional view taken along a line XXX-XXX of the active matrix substrate shown in FIG. 28;

FIG. 31 is a plan view for explaining the manufacturing method of the active matrix substrate according to the first embodiment;

FIG. 32 is a cross-sectional view taken along a line XXXII-XXXII of the active matrix substrate shown in FIG. 31;

FIG. 33 is a plan view for explaining the manufacturing method of the active matrix substrate according to the first embodiment;

FIG. 34 is a plan view for explaining a method of manufacturing an active matrix substrate according to a second embodiment;

FIG. 35 is a plan view for explaining the manufacturing method of the active matrix substrate according to the second embodiment;

FIG. 36 is a plan view for explaining the manufacturing method of the active matrix substrate according to the second embodiment;

FIG. 37 is a plan view for explaining the manufacturing method of the active matrix substrate according to the second embodiment;

FIG. 38 is a plan view for explaining the manufacturing method of the active matrix substrate according to the second embodiment;

FIG. 39 is a plan view for explaining the manufacturing method of the active matrix substrate according to the second embodiment;

FIG. 40 is a plan view for explaining the manufacturing method of the active matrix substrate according to the second embodiment;

FIG. 41 is a plan view showing an element forming substrate on which elements manufactured by a conventional manufacturing method have been formed;

FIG. 42 is an enlarged plan view of an element shown in FIG. 41;

FIG. 43 is an enlarged plan view of a thin film transistor (TFT) formed in the element shown in FIG. 42;

FIG. 44 is a plan view for explaining a conventional method of manufacturing an active matrix substrate;

FIG. 45 is a plan view for explaining the conventional manufacturing method of the active matrix substrate;

FIG. 46 is a plan view for explaining the conventional manufacturing method of the active matrix substrate;

FIG. 47 is a plan view for explaining the conventional manufacturing method of the active matrix substrate;

FIG. 48 is a plan view for explaining a modified example of a conventional active matrix substrate;

FIG. 49 is a conceptual diagram for explanation of a usage of a transcription destination substrate in a display; and

FIG. 50 is a conceptual diagram for explanation of a usage of the transcription destination substrate in the display.

### DETAILED DESCRIPTION OF THE INVENTION

Hereinafter, embodiments according to the present invention will be described with reference to the drawings.

### First Embodiment

First, a method of manufacturing an active matrix substrate according to a first embodiment of the present invention will be described. Note that, in the following description, components having the same or substantially the same functions and structures are denoted with the same reference numerals.

With respect to the method of manufacturing an active matrix substrate in the present embodiment, explanation will be given of a series of processes of preparing an active matrix substrate in which an separation layer and an undercoat layer are formed on an element forming substrate, elements including TFTs are formed, and the adjacent elements are separated in a plane of the substrate, the elements are transcribed onto an intermediate transcription substrate and in turn further transcribed onto a transcription destination substrate, and then wirings are formed.

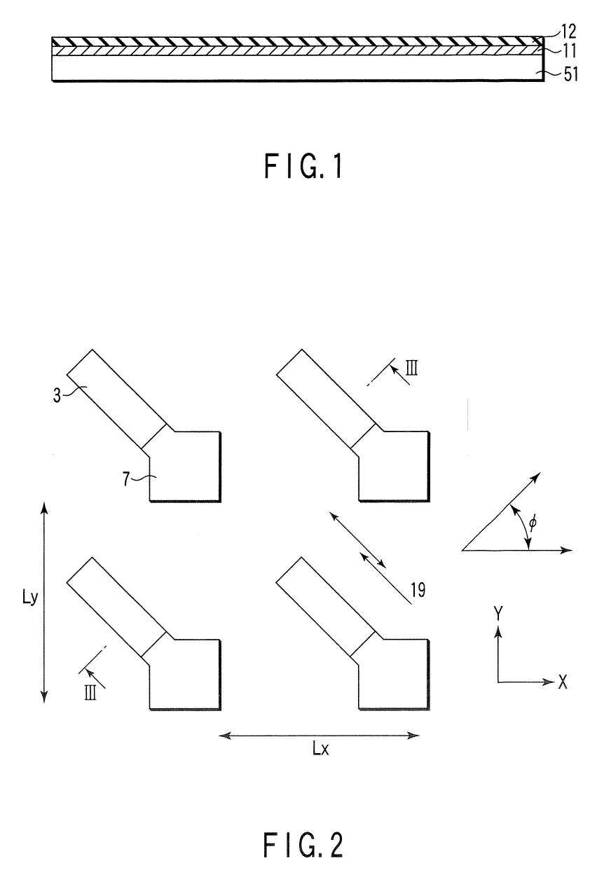

First, as shown in FIG. 1, an separation layer 11 of about 100 nm and an undercoat layer 2 of about 100 nm are sequentially formed on an element forming substrate 51 made of non-alkali glass. It suffices for the separation layer 11 to have a function to an extent that the elements can be separated from the element forming substrate 51 in a process of separating the element forming substrate 51 which will be carried out later. As a method of separating the element forming substrate, there may be used a method in which a laser such as an excimer laser is irradiated onto the element forming substrate 51 to reduce an adhesion force between the elements and the element forming substrate 51. In this case, a film of an amorphous-Si or the like may be used as the separation layer 11. Alternatively, etching is used to remove the element forming substrate 51 as the separating method. In this case, it suffices for the separation layer 11 to function as an etching stopper at the time of etching the element forming substrate 51, and a metal oxide film such as a tantalum oxide film, a silicon nitride film, or the like may be used as the separation layer 11. In addition, a silicon oxide film, a silicon nitride film, or the like may be used as the undercoat layer 12. Note that the element forming substrate 51 is not limited to non-alkali glass, and a substrate made of another material such as silicon may be used.

Next, a method in which TFTs 2 are formed in a matrix form on the undercoat layer 12 of the element forming substrate 51, and are separated in a plane of the substrate will be described with reference to FIGS. 2 to 11. TFTs 2 are formed at a pitch of 60 μm in both of the X-direction and the Y-direction of the element forming substrate 51. The TFTs 2 are formed such that a channel direction in which electric current flows is at an angle of 45° relative to the X direction. In the present embodiment, a bottom gate type amorphous-Si TFT is described as an example. However, it is not limited thereto, and it may be a top gate type amorphous-Si TFT, a bottom gate type polysilicon TFT, or a top gate type polysilicon TFT.

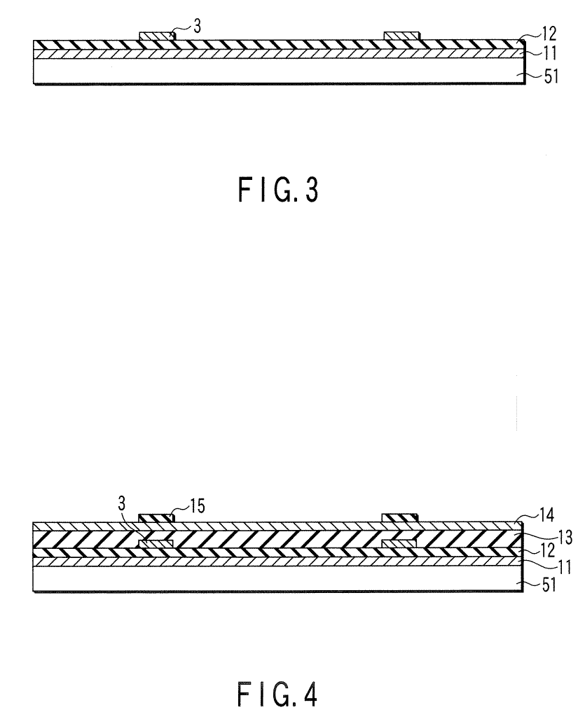

First, a material film for the gate electrode 3 is formed on the undercoat layer 12 of the element forming substrate 51. As a material film for the gate electrode 3, a metal film such as Al, Ta, Me, and Ti with a thickness of about 100 to 500 nm, a film stack of those metal films, an alloy film such as Mo—W, Mo—Ta, or Al—Nd, a film stack of these alloy films, or a film stack of these metal films and alloy films may be used. Such material films can be formed by, for example, sputtering. By patterning the formed material film, gate patterns each formed of a gate electrode 3 and a gate electrode contact pad 7 are formed simultaneously in a matrix form as shown in FIGS. 2 and 3. The gate electrode 3 and the gate electrode contact pad 7 of each of the gate patterns are formed of the same layer. With respect to the gate electrode 3, as shown in FIG. 2, a pitch Lx in the X direction and a pitch Ly in the Y direction are 60 μm, a width thereof is 30 μm, and a length thereof is 12 μm. The gate electrode contact pads 7 are formed to be adjacent to the gate electrodes 3 in a direction of the width of the gate electrodes 3 and to have a size of 20 μm square. In each of the gate pattern, the gate electrode 3 and the gate electrode contact pad 7 are formed of the same layer, and thus are electrically connected to each other. An angle φ of the channel direction 19 of the TFT 2 relative to the X direction is 45°.

Next, a gate insulating film 13 formed of a silicon oxide film, a silicon nitride film or the like is formed to have a thickness of about 100 to 500 nm over the surface of the element forming substrate 51 to cover the gate electrodes 3 by a plasma chemical vapor deposition (CVD) method. Thereafter, an amorphous-Si film is formed as a semiconductor layer 14 to have a thickness of about 30 to 200 nm over the gate insulating film 13, and a silicon nitride film 15 is formed as a channel protective film material to have a thickness of about 30 to 200 nm over the semiconductor layer 14. Then, the silicon nitride film 15 is patterned in self-align with the gate electrode 3, by exposing from the back surface of the substrate 51, so that a channel protective film 15 is provided (FIG. 4). A width of the channel protective film 15 in the channel direction 19 is 10 μm, and a length thereof is 25 μm in the present embodiment.

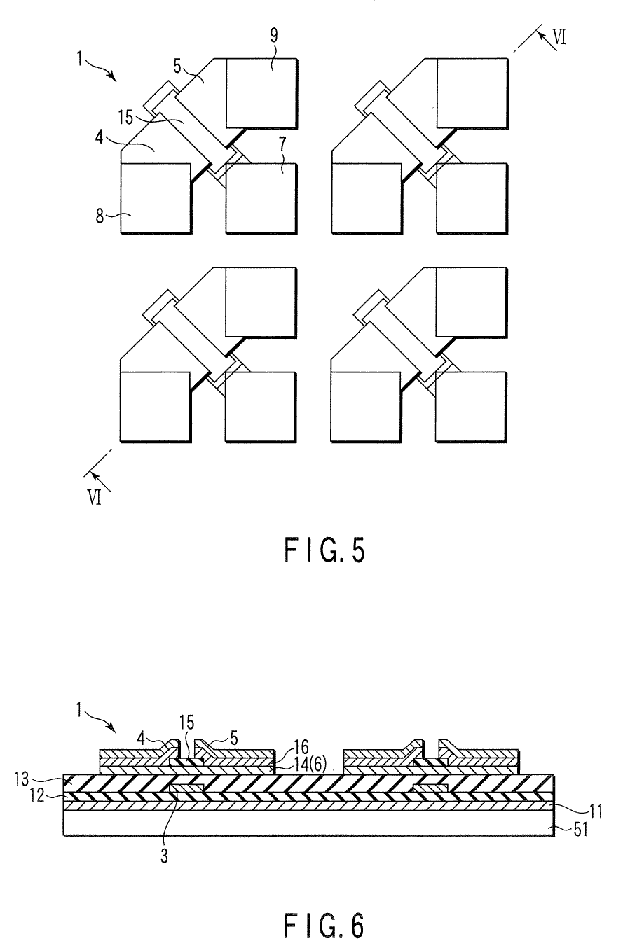

Subsequently, an n-type semiconductor layer 16 doped with phosphorus is formed to be about 30 to 100 nm over the element forming substrate 51 by a plasma CVD method, and then, a metal thin film is formed over the semiconductor layer 16. Thereafter, the metal thin film is patterned to have an opening portion on the channel protective film 15 so that the source electrode 4 and the drain electrode 5 are formed from the metal thin film (FIG. 5). Moreover, patterning is carried out onto the n-type semiconductor layer 16 and the semiconductor layer 14 (FIG. 6). At this time, the semiconductor layer 14 under the source electrode 4, the drain electrode 5, and the channel protective film 15 remains un-etched, and a part of the remaining semiconductor layer 14 forms the channel portion 6. As a thin film forming the source electrode 4 and the drain electrode 5, a metal film such as Al, Ta, Mo, or Ti having a thickness of about 100 to 500 nm, an alloy film such as Mo—W, Mo—Ta, or Al—Nd, or a film stack of such can be used. The source electrode 4 and the drain electrode 5 can be formed by carrying out sputtering or the like to form a film, and then, patterning the film. At the same time the source electrode 4 and the drain electrode 5 are formed, the source electrode contact pad 8 and the drain electrode contact pad 9 respectively having sizes of 20 μm square are formed from the same layers of the source electrode 4 and the drain electrode 5, respectively (FIG. 5). As a consequence, the source electrode 4 and the source electrode contact pad 8 are electrically connected to each other, and the drain electrode 5 and the drain electrode contact pad 9 are electrically connected to each other.

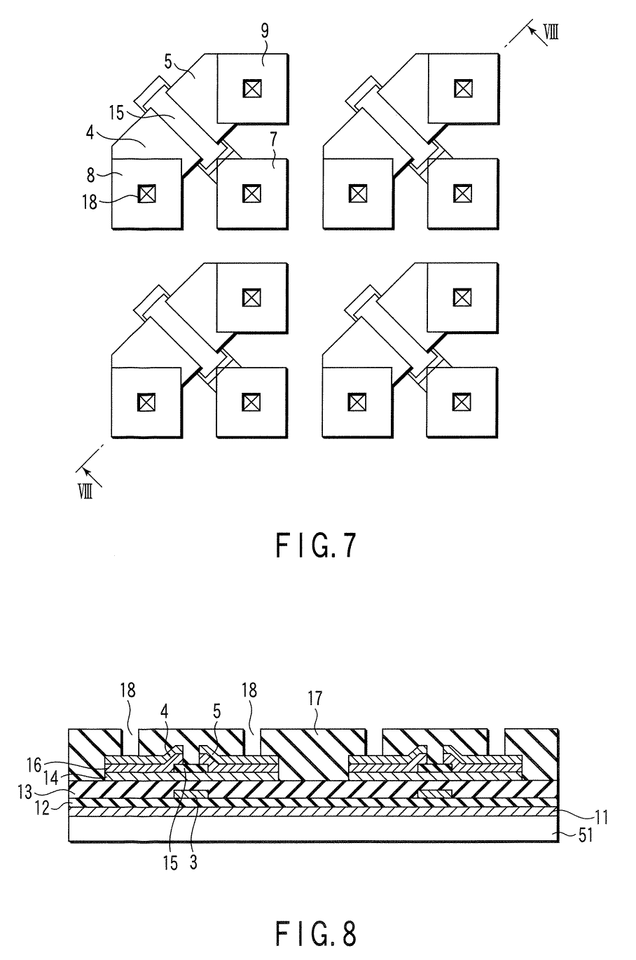

Next, a passivation film 17 formed of a silicon nitride film is formed to be 100 to 300 nm over the element forming substrate 51 by plasma CVD. Thereafter, by etching, contact holes 18 having a size of 5 μm are formed at portions of the passivation film 17, which are on the central portions of the gate electrode contact pad 7, the source electrode contact pad 8, and the drain electrode contact pad 9 (FIGS. 7 and 8). As described above, the elements 1 are formed in a matrix form on the element forming substrate 51.

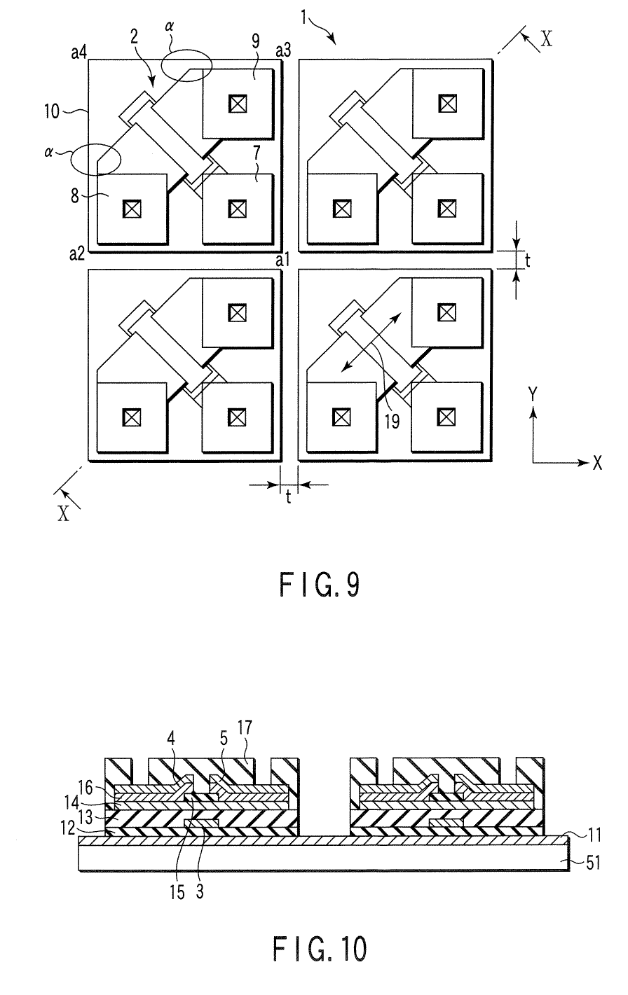

Subsequently, part of the passivation film 17, part of the gate insulating film 13 and part of the undercoat layer 12, which are outside the peripheral sides 10 of the elements, are removed by etching, to define the peripheral sides 10 of the elements 1, so that the elements 1 are separated from one another in the plane of the element forming substrate 51 (FIGS. 9 and 10). Examples of this etching include wet-etching using an hydrofluoric acid etchant such as BHF (a compound liquid of hydrofluoric acid and ammonium fluoride), and dry etching in which reactive ion etching, chemical dry etching, or the like is carried out by using a fluorine gas such as sulfur hexafluoride (SF₆) or carbon tetrafluoride (CF₄). Etching is not carried out for the separation layer 11, which remains over the element forming substrate 51.

Distances between the peripheral sides 10 of the adjacent elements 1 are made to be 4 μm in both of the X-direction and the Y-direction, and the element 1 has a square shape of 56 μm square. Note that the shape of the element 1 is not limited to a square, and may be a rectangle, a parallelogram, or a rhombus. Further, the source electrode contact pad 8 and the drain electrode contact pad 9 are respectively arranged to be close to the two interior corners a2 and a3 that are opposite each other among four interior corners a1 to a4 of the element 1 configured by a square. These contact pads are arranged to be distant by 3 μm from the peripheral sides 10. The gate electrode contact pad 7 is arranged to be close to the one interior corner a1 among the interior corners a1 and a4. Differently from the cases of the interior corners a1, a2 and a3, no contact pad is arranged at a portion close to the interior corner a4. The TFT 2 is formed in the central area of the element 1, and the end of the channel portion 6 of the TFT 2 is distant from the interior corner a4 by 10 μm or more. None of the gate electrode contact pad 7, the source electrode contact pad 8, and the drain electrode contact pad 9 are formed between the interior corner a4 and the TFT 2. The channel direction 19 in which an electric current flows in the channel portion 6 of the TFT 2 is inclined at 45° relative to the peripheral sides 10 of the element 1.

As described above, because the TFT 2 is provided in the central area of the element 1, and the channel portion 6 is distant by 10 μm or more from the interior corner of the peripheral sides 10 of the element 1, damage to the elements by side etching or permeation of etchant in a process of separating the adjacent elements does not occur. Note that, even if slight side etching or permeation of etchant is brought about in portions in the vicinity of the peripheral side 10 surrounded by ◯ marks which are shown by α in the semiconductor layer 14 in FIG. 9 in a process of isolating the adjacent elements, no damage occurs in the channel portion 6. Further, because the source electrode and the drain electrode made of metal have low resistance, there is scarcely any variation in the properties of the TFT 2. The gate electrode contact pad 7, the source electrode contact pad 8, and the drain electrode contact pad 9 are also in the vicinity of the peripheral side 10. However, even if there is slight side etching or permeation of etchant in a process of separating the adjacent elements, the patterns of the electrode contact pads are large, and therefore, the TFT 2 offers high resistance against breaking and variation of properties.

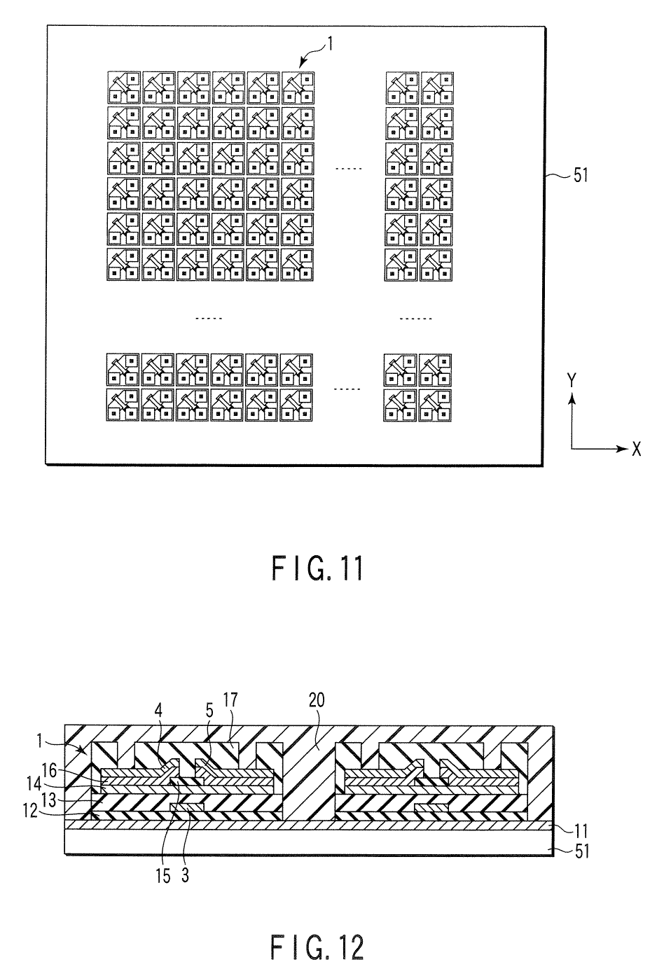

The element forming substrate 51 on which the elements 1 have been arranged in a matrix form by the above-described method is shown in FIG. 11. The elements 1 are formed in a matrix form to coincide with the X and Y directions of the element forming substrate 51. The directions of the peripheral sides 10 of the element 1 are parallel to the X or Y direction of the element forming substrate 51. The channel of the transistor formed in the element 1 is arranged such that the channel direction in which an electric current flows is inclined relative to the peripheral sides 10 of the element 1. In other words, the channel of the transistor is arranged such that the channel direction is inclined relative to the array direction of the elements formed in a matrix form on the substrate. In this way, since the channel of the transistor formed in the element 1 is arranged to be inclined relative to the peripheral sides 10 of the element 1, in other words, since the channel is arranged to be inclined relative to the array direction of the elements, the density of the elements formed on the element forming substrate 51 is prevented from being reduced. Further, the peripheral sides 10 of the element 1 form a square, the TFT 2 is arranged in the central area of the element 1, and no electrode or semiconductor layer is arranged at one interior corner among the four interior corners of the square. This makes it possible to prevent a defect from occurring in the TFT 2 due to side etching or permeation of etchant at the time of separating the elements in the plane of the substrate.

Next, a method of transcribing the TFTs 2 from the element forming substrate 51 to the intermediate transcription substrate 21 will be described with reference to FIGS. 12 to 17.

A protection layer 20 made of an organic resin is formed to cover the elements 1 over the surface of the element forming substrate 51 (FIG. 12). As an organic resin forming the protection layer 20, a novolak resin, a polyimide resin, an acrylic resin, a cresol resin, a toluene resin, a phenol resin, or the like can be used, however, no limit is imposed thereto. It suffices for a thickness of the protection layer 20 to be about 0.05 to 5 μm. In this embodiment, the protection layer 20 is made of a phenol resin with a thickness of 0.5 μm by volatilizing the solvent by baking after coating a compound liquid of a phenol resin and a solvent by a spin coat method.

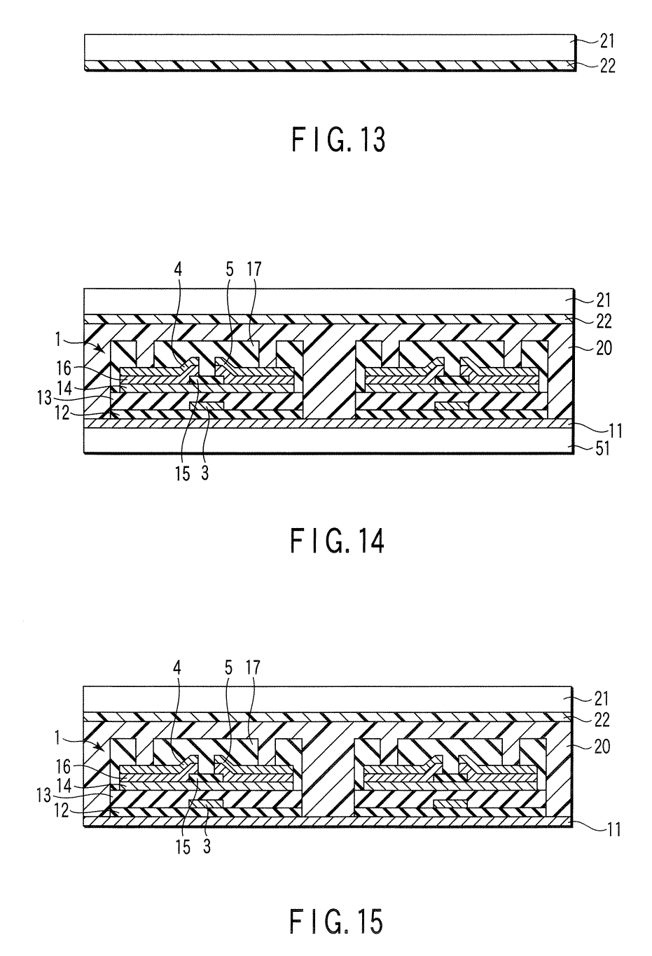

Then, the intermediate transcription substrate 21 having a temporary adhesion layer 22 formed on one surface thereof is prepared (FIG. 13). The temporary adhesion layer 22 is preferably made of a material whose adhesion force is reduced by, for example, adding heat or light externally. As the intermediate transcription substrate 21, non-alkali glass, quartz, soda lime, an Si substrate, a stainless plate, an aluminum plate, aluminum foil, or the like can be used. Alternatively, a plastic film such as PET, PEN, or polyester can be used as the intermediate transcription substrate 21. When a temporary adhesion layer whose adhesion force is reduced by irradiating light is used, it suffices to select a material through which a light of a desired wavelength is transmittable.

Next, the protection layer 20 on the element forming substrate 51 and the temporary adhesion layer 22 on the intermediate transcription substrate 21 are faced and adhered to each other (FIG. 14).

Subsequently, the element forming substrate 51 is separated from the elements 1 (FIG. 15). When amorphous-Si is used as the separation layer 11, an excimer laser is irradiated from the element forming substrate 51 side as a method of separating the element forming substrate 51. As a consequence, ablation (interface friction) is brought about between the amorphous-Si forming the separation layer 11 and the non-alkali glass forming the element forming substrate 51, which reduces an adhesion force between the separation layer 11 and the undercoat layer 12. The element forming substrate 51 is separated from the elements 1 by drawing the element forming substrate 51 in this state. When glass is used as the element forming substrate 51, the element forming substrate 51 may be removed by etching using an etchant including hydrofluoric acid. When the element forming substrate 51 is removed by etching, it suffices for the separation layer 11 to function as an etching stopper at the time of etching the element forming substrate 51. For this reason, for example, a metal oxide film such as a tantalum oxide film, a nitride film, a silicon film, a silicon nitride film, or the like may be used, or, a film stack of such may be used.

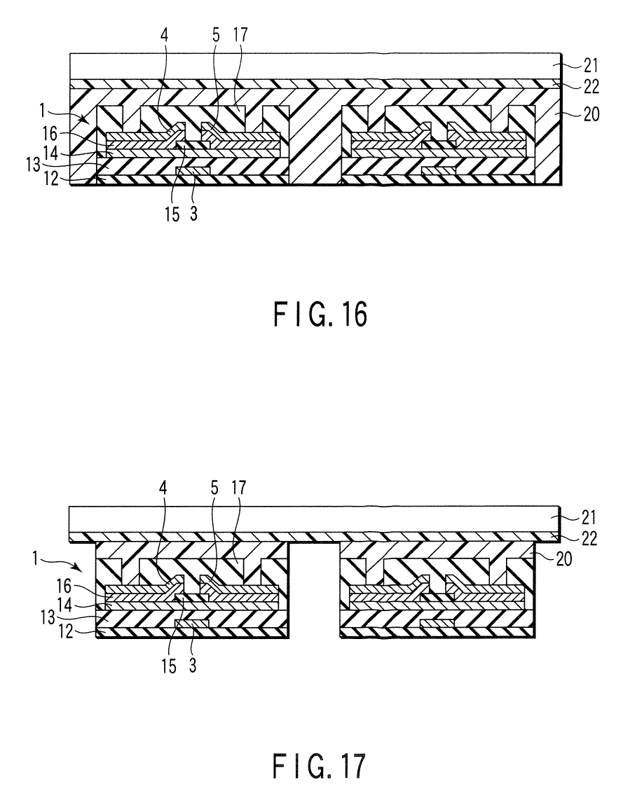

Then, the separation layer 11 is removed by wet-etching using TMAH (tetramethylammonium hydro-oxide) or the like, or dry etching such as reactive ion etching, chemical dry etching, or the like which uses a fluorine gas such as sulfur hexafluoride, or carbon tetrafluoride (FIG. 16).

After removing the separation layer 11, the protection layer 20 existing among adjacent elements 1 is removed (FIG. 17). As a method of removing the protection layer 20, the protection layer 20 existing among the adjacent elements 1 may be removed by ashing in which plasma including oxygen is irradiated from the opposite side of the intermediate subscribing substrate 21 side, i.e., from the undercoat layer 12 side. Alternatively, as a method of removing the protection layer 20, the protection layer 20 existing among the adjacent elements 1 may be removed by being dissolved by immersing the elements 1 in a solvent. In this way, the elements 1 are transcribed in the form that the elements 1 are separated from one another in a plane of the substrate, on the intermediate subscribing substrate 21.

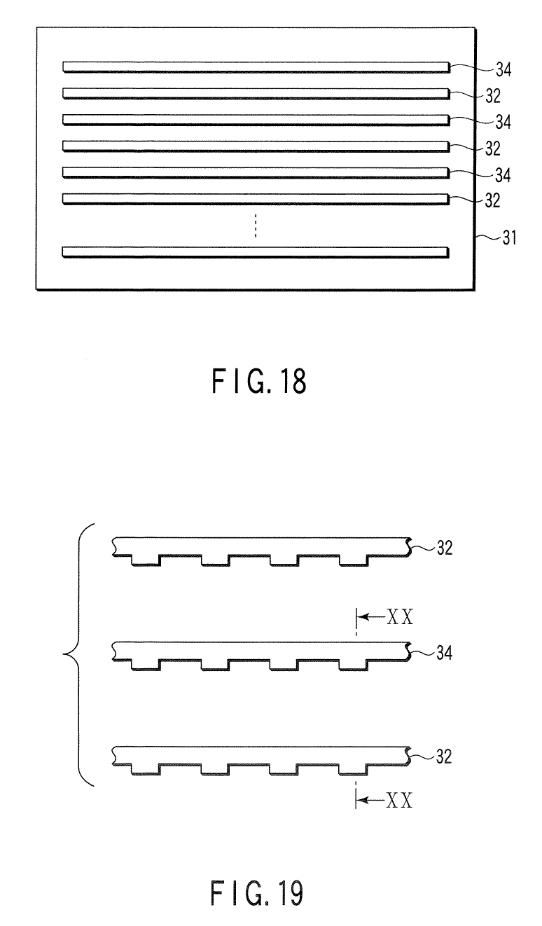

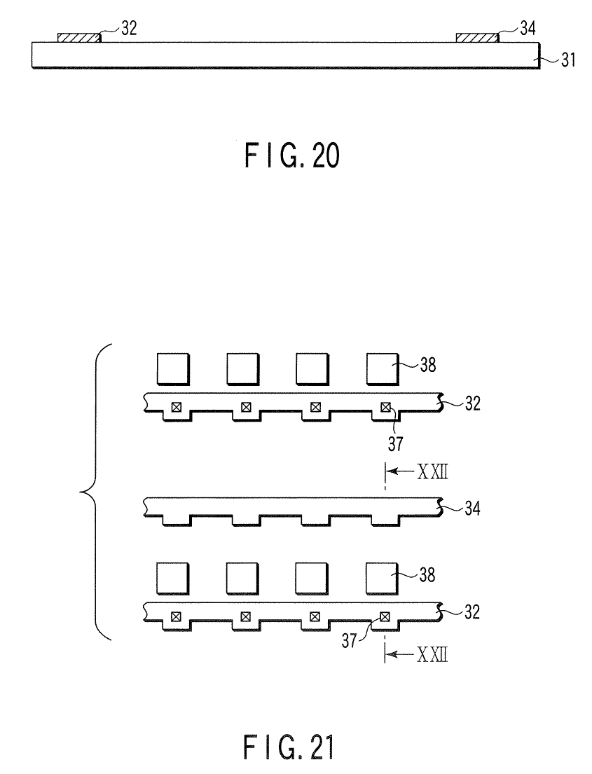

Next, explanation will be given of processes for manufacturing an active matrix substrate by transcribing the elements 1 from the intermediate transcription substrate 21 to a transcription destination substrate 31 with reference to FIGS. 18 to 33.

First, a metal film such as Al, Ta, Me, or Ti, or an alloy film such as Mo—W, Mo—Ta, or Al—Nd, or a film stack of such films is formed on a prepared transcription destination substrate 31 by sputtering. Then, gate lines 32 and storage capacitor lines 34 having a thickness of about 100 to 500 nm and a line width of about 10 to 30 μm are formed from the formed film by etching using a photolithography method, as shown in FIGS. 18-20. In FIG. 19, a part of the gate lines 32 and the storage capacitor line 34 is shown in an enlarged scale. As shown in FIG. 18, the gate lines 32 and the storage capacitor lines 34 are formed to be alternately parallel to each other on the transcription destination substrate 31. Here, if a pitch of the elements 1 on the transcription destination substrate 31 is designed to be an integral multiple of the pitch of the elements 1 on the element forming substrate 51, a plurality of elements 1 can be transcribed simultaneously, which makes the transcription process efficient. For example, the pitch of the elements 1 on the transcription destination substrate 31 is 120 μm in the X-direction, and to be 360 μm in the Y-direction.

In this case, it suffices for pitches of both of the gate lines 32 and the storage capacitor lines 34 to be 360 μm, and it suffices for a pitch of signal lines 33 to be described later to be 120 μm. Because the pitch of the elements 1 on the element forming substrate 51 is 60 μm in both of the lateral direction and the vertical direction, the pitch of the gate lines 32 is six times the pitch of the TFTs 2, and the pitch of the signal lines 33 which will be formed later is double the pitch of the TFTs 2. In addition to non-alkali glass, a plastic film or the like with flexibility can be used as the transcription destination substrate 31.

Note that the gate lines 32 and the storage capacitor lines 34 may be formed by an evaporation method, a screen printing method, an inkjet method, and the like, in addition to the forming method described above.

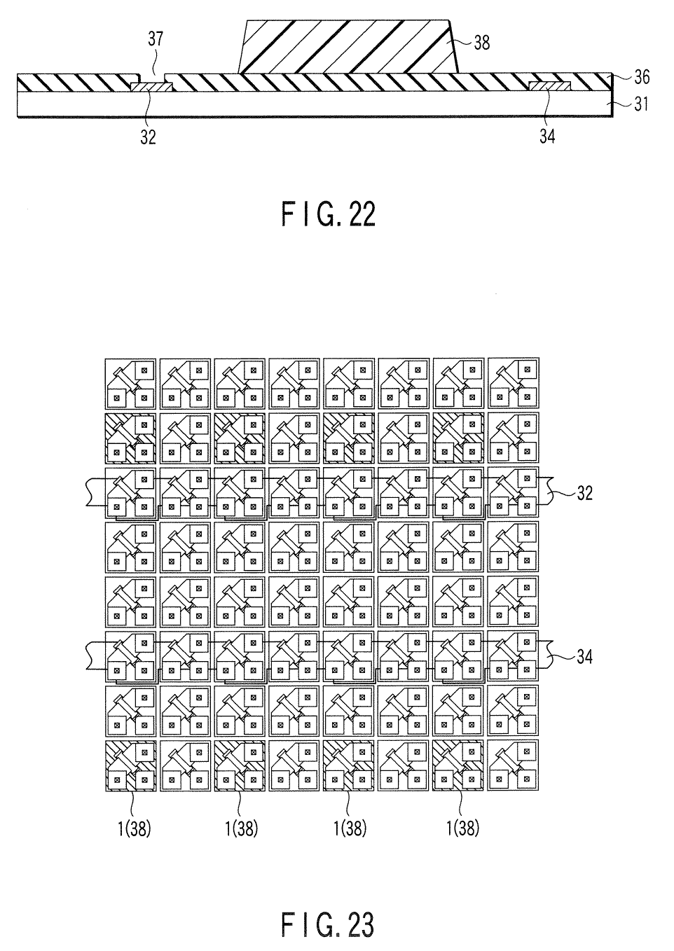

Subsequently, an interlayer insulation film 36 is formed to have a thickness of 0.2 to 0.5 μm on the transcription destination substrate 31. Then, adhesion layers 38 are formed on portions of the interlayer insulation film 36, onto which the elements 1 are to be transcribed. Then, through-holes 37 for gate line contact are formed at the interlayer insulation film 36 such that the surfaces of the gate lines 32 are exposed (FIGS. 21 and 22). The size of the bottom surface of the adhesion layer 38 is about 60 μm square, and the thickness of the adhesion layer 38 is about 1 to 5 μm. The interlayer insulation film 36 may be formed by carrying out a plasma CVD or sputtering onto an inorganic insulating material, or may be formed by applying an organic film such as polyimide, an acrylic resin, or benzo-cyclobutene (BCB). The adhesion layer 38 may be formed by applying an adhesion material by screen printing or the like, or may be formed by applying and exposing photosensitive acrylic. Further, the adhesion layer 38 may be made opaque by dispersing fine grains of metal such as Cr in the adhesion layer 38, or, a black resist may be used as a material of the adhesion layer 38. In this way, by making the adhesion layer 38 opaque or black, leakage of light into the active elements to be transcribed on the adhesion layer 38 is reduced, and a switching ratio of the transistors can be improved, which leads to improvement in image quality of the display unit eventually formed. If an organic resin with photosensitivity is used as a material of the adhesion layer 38, patterning using photolithography is possible, and further, the cost is reduced more than in the case of using a resin without photosensitivity. An organic resin without photosensitivity may be used as a material of the adhesion layer 38. In that case, patterning can be carried out onto the adhesion layer 38 by etching, printing, or the like.

Next, the elements 1 on the intermediate transcription substrate 21 are transcribed onto the transcription destination substrate 31.

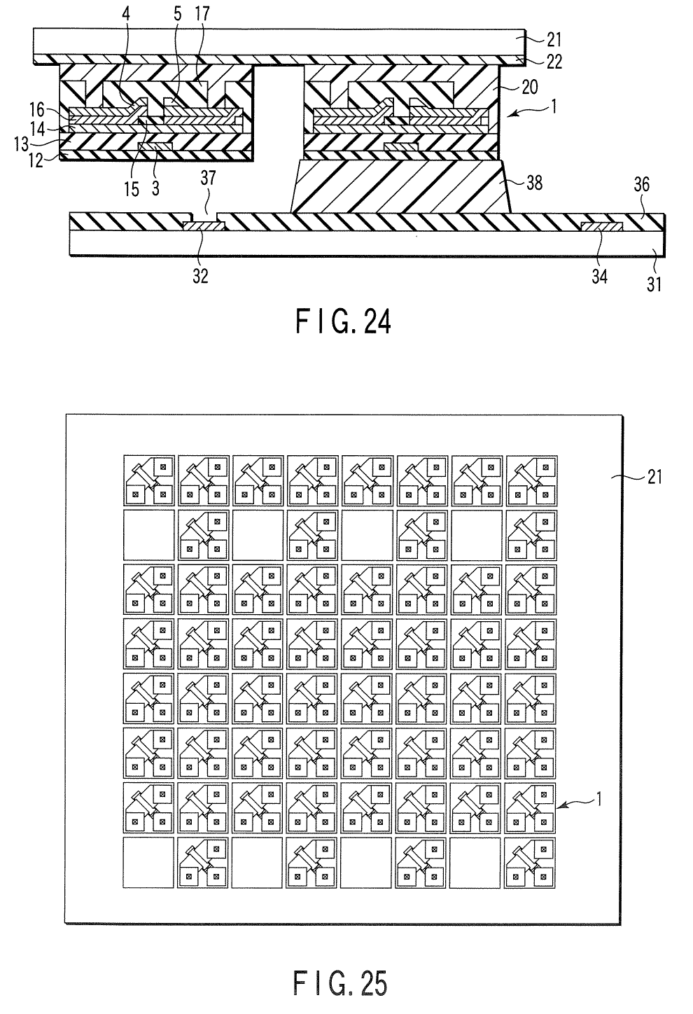

As shown in FIG. 23, the intermediate is transcription substrate 21 and the transcription destination substrate 31 are overlapped in order to transcribe the elements 1 on the intermediate transcription substrate 21 onto the transcription destination substrate 31 having the gate lines 32, the storage capacitor lines 34 and the adhesion layers 38 formed thereon. However, to facilitate an understanding thereof, the intermediate transcription substrate 21 is omitted in the drawing. As shown in FIG. 24, a predetermined pressure is applied to the transcription destination substrate 31 and the intermediate transcription substrate 21 in a state in which the adhesion layers 38 on the transcription destination substrate 31 and the elements 1 on the intermediate transcription substrate 21 are made to be faced and overlapped one another. The adhesion force of the temporary adhesion layer 22 is reduced by applying heat or light externally in this state, and the transcription destination substrate 31 and the intermediate transcription substrate 21 are separated in this state, so that the elements 1 are transcribed from the intermediate transcription substrate 21 to the transcription destination substrate 31.

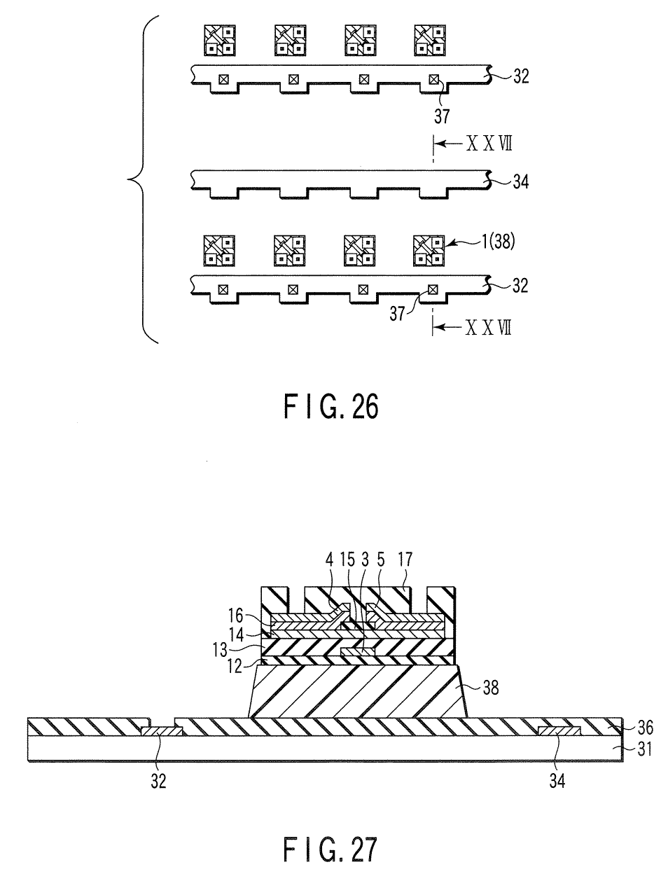

The intermediate transcription substrate 21 after the elements 1 are transcribed from the substrate 21 to the transcription destination substrate 31 is shown in FIG. 25. The transcription destination substrate 31 after the elements 1 are transcribed from the intermediate transcription substrate 21 to the substrate 31, as shown in FIG. 26. As shown in FIGS. 25 and 26, the elements 1 formed on the intermediate transcription substrate 21 are removed from the intermediate transcription substrate 21 in a pitch of one per twelve and disappeared from the intermediate transcription substrate 21. The removed elements 1 are transcribed on the transcription destination substrate 31. By repeating the above element transcription processes, the elements 1 can be transcribed on all the adhesion layers 38 on the transcription destination substrate 31 so that the elements 1 are arranged in a matrix form on the transcription destination substrate 31, as shown in FIG. 26. After the elements 1 are transcribed from the intermediate transcription substrate 21 onto the transcription destination substrate 31 as described above, the protection layer 20 remaining on the elements transcribed on the transcription destination substrate 31 is removed (FIG. 27). As a method of removing the protection layer 20, the protection layer 20 remaining on the elements 1 may be removed by ashing in which plasma including oxygen is irradiated from the opposite side of the transcription destination substrate 31. As a method of removing the protection layer 20, the protection layer 20 remaining on the elements 1 may be removed by being dissolved by immersing the entire elements 1 in a solvent. However, in the both cases, it is necessary to appropriately set conditions for removal in order to avoid damage to the interlayer insulation film 36 and the adhesion layers 38 by the removal processings.

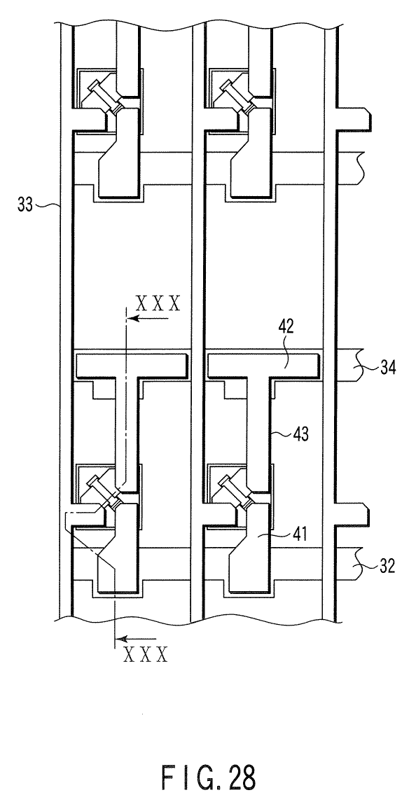

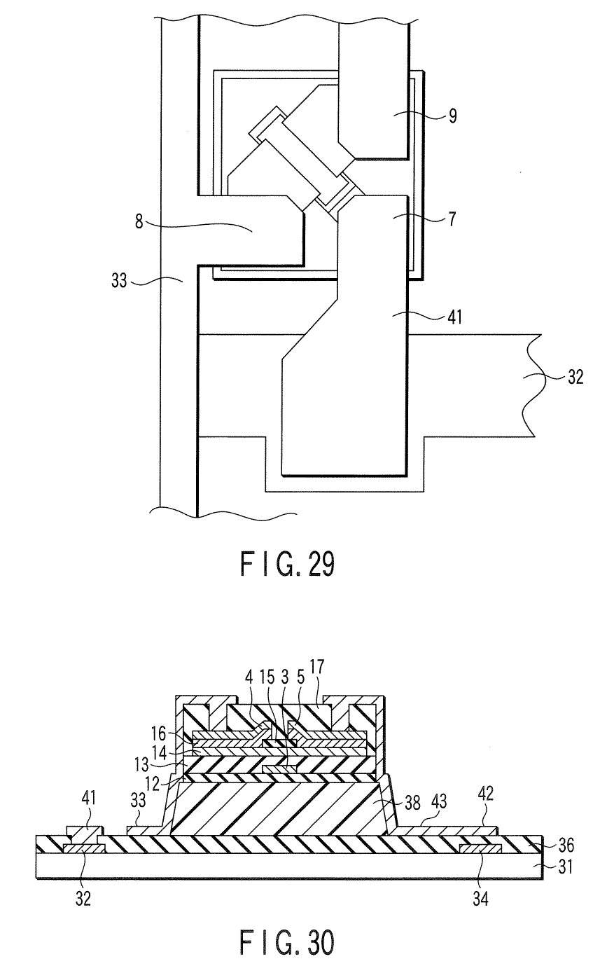

Subsequently, the signal lines 33 are formed on the transcription destination substrate 31. A part of a pixel region in which the signal lines 33 have been formed, is shown in FIG. 28. The vicinity of the element 1 of FIG. 28 is shown in a large scale in FIG. 29. First, as shown in FIGS. 28 and 29, the signal line 33 is made of the same material as that of the gate line 32. At this time, the signal line 33 is made to connect to the source electrode contact pad 8 connected to the source electrode 4 of the TFT 2. Moreover, at the same time when the signal line 33 is formed, a contact wiring 41 for connecting the gate line 32 to the gate electrode contact pad 7 connected to the gate electrode 3, a storage capacitor electrode 42, and a contact wiring 43 for connecting the storage capacitor electrode 42 to the drain electrode contact pad 9 connected to the drain electrode 5 are formed in the same manner. A storage capacitor is formed between the storage capacitor line 34 and the storage capacitor electrode 42.

The preferable range of overlap of the signal line 33 and the source electrode contact pad 8, overlap of the contact wiring 41 and the gate electrode contact pad 7, and overlap of the contact wiring 43 and the drain electrode contact pad 9 is 10 μm or less from the centers of the respective electrode contact pads. If the overlap range is as above, it is possible to establish satisfactory electric connections between the gate line 32 and the gate electrode contact pad 7, between the signal line 33 and the source electrode contact pad 8, and between the storage capacitor electrode 42 and the drain electrode contact pad 9 even if there is deformation or misalignment during the process of forming an active matrix substrate.

Further, distances of the signal line 33, the contact wiring 41, and the contact wiring 43 respectively from the channel portion 6 of the TFT 2 are preferably made greater than or equal to 7 μm. When the distances are greater than or equal to 7 μm, it is possible to prevent generation of a paratitic capacitance or malfunction due to the wirings, the pixel electrodes, and portions having the same potential as those being overlapped onto the channel portion 6 of the TFT 2 even if there is deformation or misalignment in a process of forming an active matrix substrate.

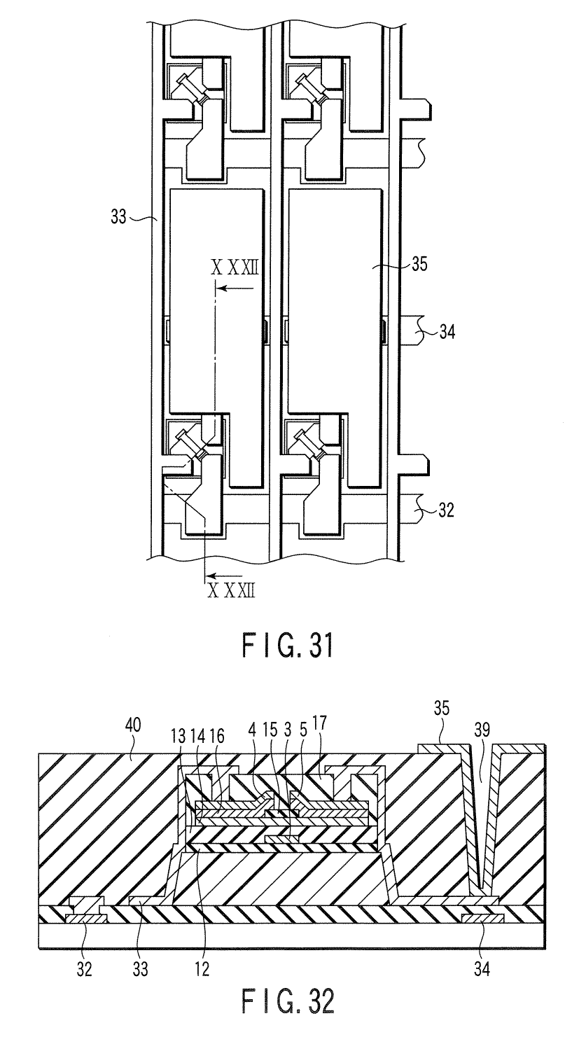

Next, a planarizing film 40 is formed on the transcription destination substrate 31 including the TFT 2, and then, a pixel electrode 35 is formed. A portion of a pixel region on which the pixel electrode 35 has been formed, is shown in FIG. 31. As shown in FIG. 32, the planarizing film 40 is formed by coating an acrylic resin to be about 2 to 20 μm and by annealing the coated resin. The concavo-convex on the surface of the planarizing film 40 is less than or equal to about 0.5 μm. As the planarizing film 40, an inorganic insulating film may be formed and grinded. A through-hole 39 for contact is formed at a portion of the planarizing film 40 on the storage capacitor electrode 42. As a method of forming the through-hole 39, a resist pattern having an opening is formed on a portion of the planarizing film 40 at which the through-hole 39 is to be formed is formed on the planarizing film 40, and a through-hole is formed by exposing and etching by using this resist pattern as a mask. When a resin material having photosensitivity is used as the planarizing film 40, it may be formed by exposing and development-processing onto the planarizing film 40. After the through-hole 39 is formed, an indium tin oxide (ITO) film is formed on the planarizing film 40 by sputtering, and then, the pixel electrode 35 is formed by patterning onto the ITO film.

Note that the formation of wirings such as the gate lines 32 and the signal lines 33, the formation of the adhesive layers 38, the formation of the through-hole of the interlayer insulation film 36, and the transcription of the elements 1 from the intermediate transcription substrate 21 to the transcription destination substrate 31 may be in a different order from that as described in the present embodiment.

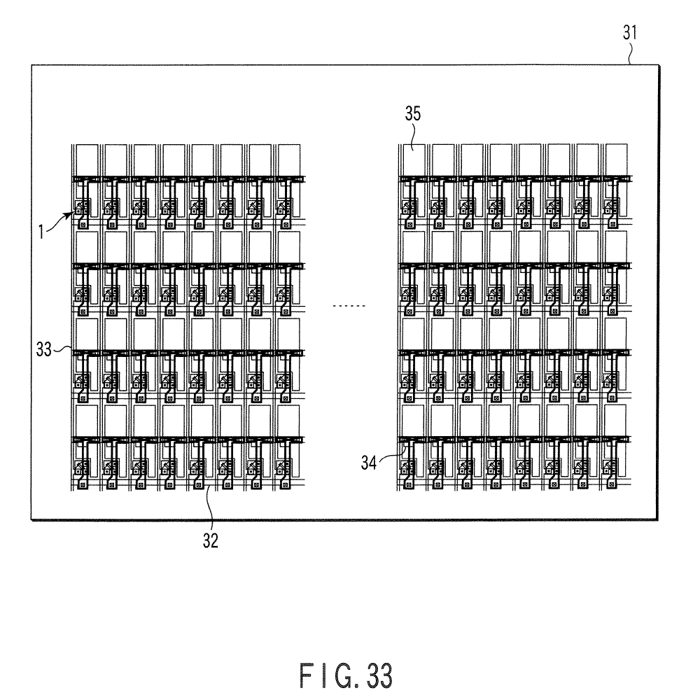

In accordance with the above processes, an active matrix substrate as shown in FIG. 33 can be manufactured, and a TFT-LCD (Thin Film Transistor-Liquid Crystal Device) can be obtained by using the active matrix substrate.

In the active matrix substrate manufactured as described above, the channel direction of the TFT 2 in the element 1 formed on the transcription destination substrate 31 is inclined relative to the direction of the wirings of the gate line 32 and the signal line 33, and therefore, deterioration in image quality and generation of a crack can be prevented by curving the substrate. Further, the peripheral sides of the element 1 form a square, the TFT 2 is arranged in the central area of the element 1, and no electrode or semiconductor layer is arranged at one interior corner among the four interior corners of the square. Consequently, a defect is prevented from occurring in the TFT 2 due to side etching or permeation of etchant at the time of separating the elements 1 in the plane of the substrate.

Note that, in the present embodiment, the TFT-LCD using an active matrix substrate has been described as an example. However, the concept of the present embodiment is not limited thereto, and can be applied to a display device, such as an organic EL display and an electrophoretic display other than an LCD. The concept of the present embodiment can be further applied to other devices using active matrix substrates such as a charge coupled device (CCD). The concept of the present embodiment can be further applied to a thin film device such as a semiconductor laser and an light emitting diode (LED).

### Second Embodiment

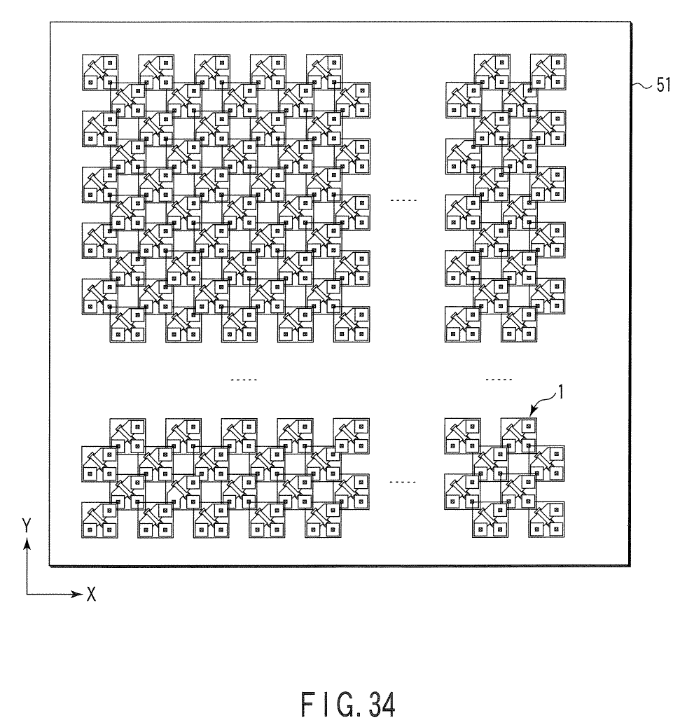

Next, a method of manufacturing an active matrix substrate according to a second embodiment will be described with reference to FIGS. 34 to 40. In the present embodiment, only portions different from those of the first embodiment will be described, and descriptions of the same portions will be omitted.

The present embodiment is different from the first embodiment in that the direction of the element 1 formed on the element forming substrate 51 is different from that in the first embodiment.

First, in the same manner as in the first embodiment, the elements 1 including the TFTs 2 are formed in a matrix form on the element forming substrate 51, and adjacent elements are separated in a plane of the substrate. The structure of the TFT 2 and the sizes of the respective electrode contact pads in the element 1 are the same as those in the first embodiment. However, the direction of the elements 1 formed on the element forming substrate 51 is different from the first embodiment.

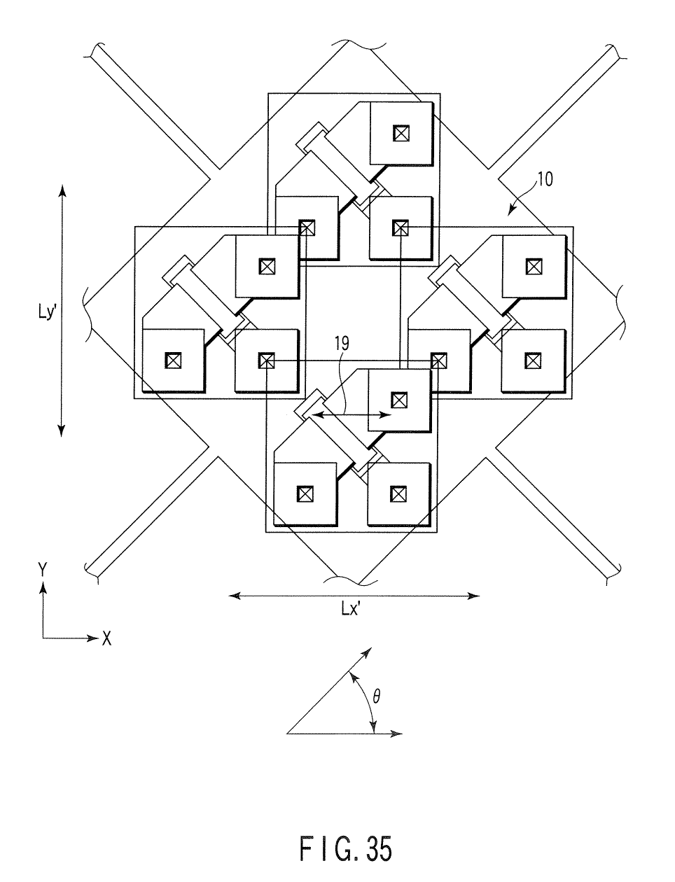

A layout drawing of the elements 1 formed on the element forming substrate 51 is shown in FIG. 34, and an enlarged view thereof is shown in FIG. 35. The angle θ in the X-direction of the element forming substrate 51 relative to the direction of the peripheral side 10 of the element 1 is 45°. Assuming that pitches in the X and Y directions of the element 1 on the element forming substrate 51 are respectively Lx′ and Ly′, both Lx′ and Ly′ are 85 μm of about √2 times the Lx and Ly in the first embodiment. Further, a channel direction of the TFT 2 is made parallel to the X direction of the element forming substrate 51. As described above, the layout of the elements 1 in the present embodiment is that of the layout of the elements 1 in the first embodiment rotated 45° clockwise.

The used method for transcribing the elements 1 formed in the above-described layout on the element forming substrate 51 onto the intermediate transcription substrate 21 to be separated in a plane of the substrate may be the same as that of the first embodiment.

With respect to the element forming substrate 51 manufactured by the above method as well, the elements 1 are arranged in a matrix form on the element forming substrate 51, and the channel of the thin film transistor is arranged so as to be inclined relative to the peripheral sides 10 of the element 1 by inclining a channel direction of the thin film transistor arranged in the element 1 relative to the peripheral sides 10 of the element 1 in the same manner as in the first embodiment. Therefore, the density of the elements on the element forming substrate 51 can be prevented from being reduced. Moreover, in the same manner in the first embodiment, the peripheral sides of the element 1 form a square, the TFT 2 is arranged in the central area of the element 1, and no electrode or semiconductor layer is arranged at one interior corner among the four interior corners of the square defining the element 1. This makes it possible to prevent a defect from occurring in the TFT 2 due to side etching or permeation of etchant at the time of separating the elements 1 in the in the plane of the substrate.

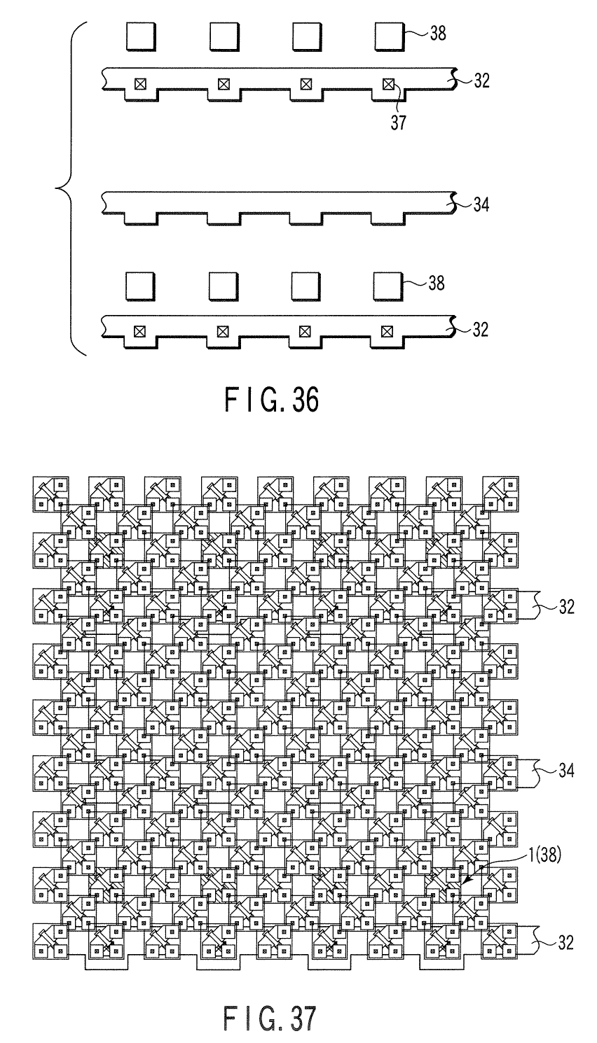

Subsequently, the gate lines 32 and the storage capacitor lines 34 are formed to be alternately parallel to one another on the transcription destination substrate 31 (FIG. 36). When a pitch of the elements 1 on the transcription destination substrate 31 is made to be an integral multiple of the Lx′ and Ly′ which are the pitch of the elements 1 on the element forming substrate 51, the transcription process can be efficiently carried out. Note that, when the both Lx′ and Ly′ are made to be 85 μm, the pitch of the elements 1 on the transcription destination substrate 31 is made to be 170 μm which is double the Lx′ in the X-direction, and to be 510 μm which is six times Ly′ in the Y-direction. In that case, both pitches of the gate lines 32 and the storage capacitor lines 34 are made to be 510 μm, and a pitch of the signal lines 33 to be described later is made to be 170 μm.

Next, in the same manner as in the first embodiment, the interlayer insulation film 36 and the adhesion layers 38 are formed on the transcription destination substrate 31 (FIG. 36). The adhesion layers 38 are formed on portions of the transcription destination substrate 31, onto which the elements 1 are transcribed. It suffices for a size of the bottom surface of the adhesion layer 38 to be about 85 μm square, and a direction thereof is made to be a direction in which it is rotated about 45° relative to the direction of the gate line 32.

Then, the elements 1 on the intermediate transcription substrate 21 are transcribed onto the transcription destination substrate 31 by the same processes as those in the first embodiment. An overlapped state of the intermediate transcription substrate 21 and the transcription destination substrate 31 is shown in FIG. 37. The substrates 21 and 31 are overlapped to each other to transcribe the elements 1 on the intermediate transcription substrate 21 onto the transcription destination substrate 31, as shown in FIG. 36, having the gate lines 32, the storage capacitor lines 34, and the adhesion layers 38 formed thereon. To facilitate an understanding thereof, the intermediate transcription substrate 21 is omitted in the drawing.

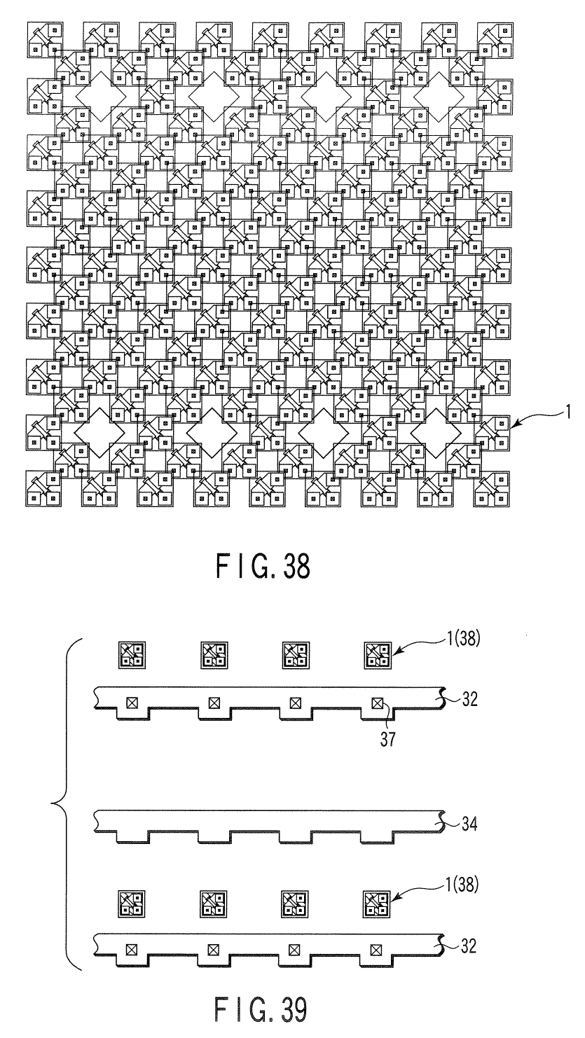

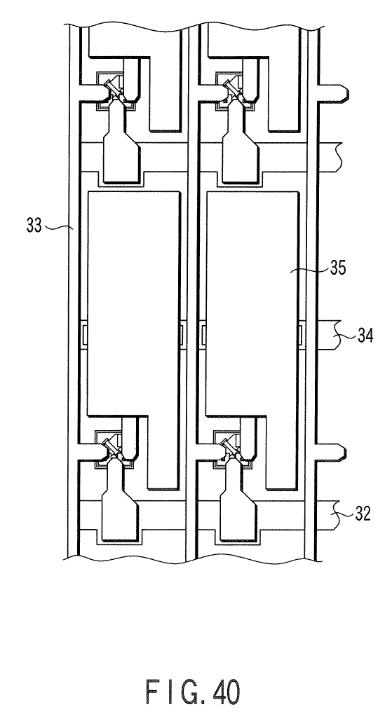

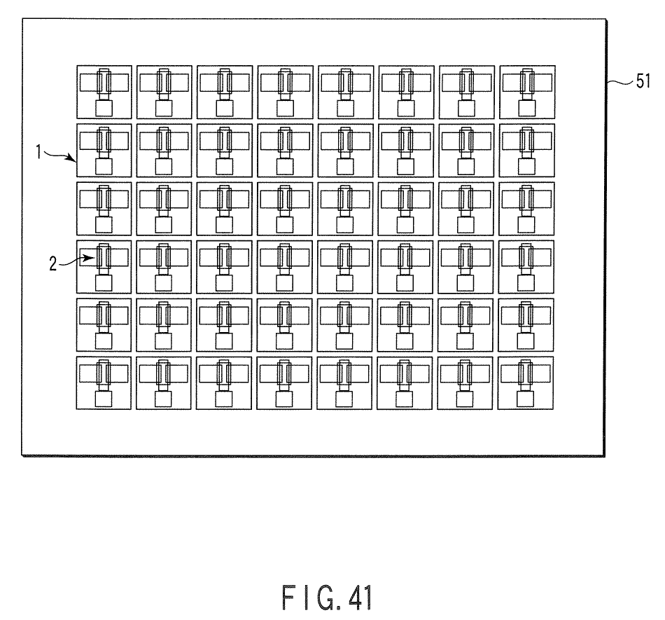

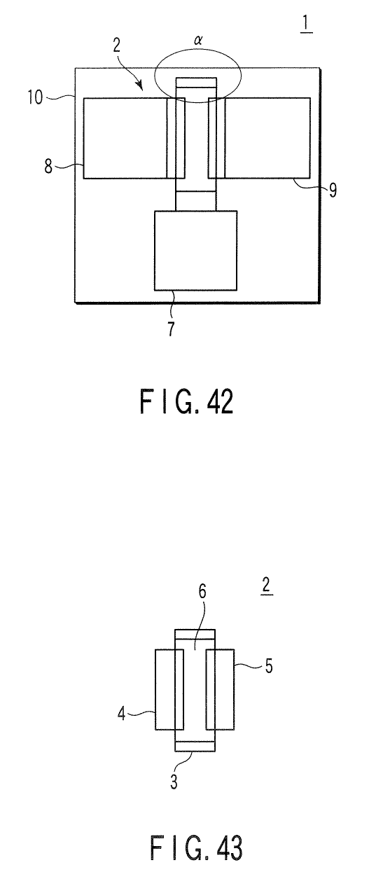

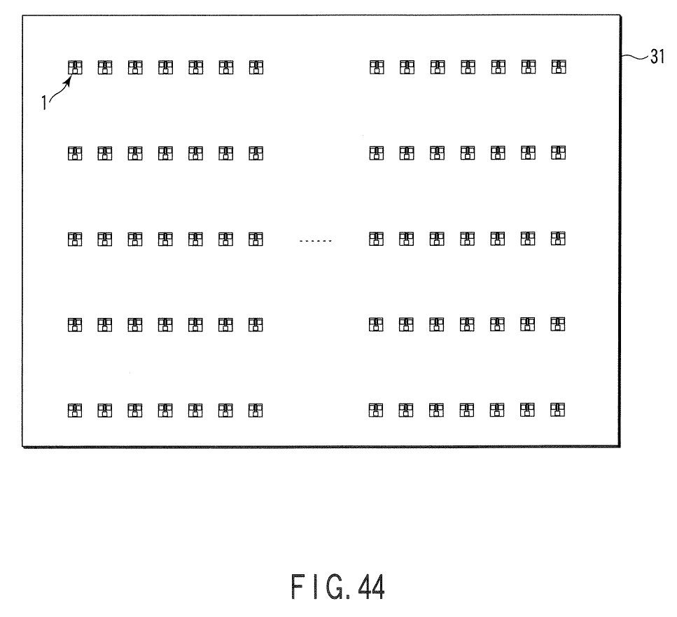

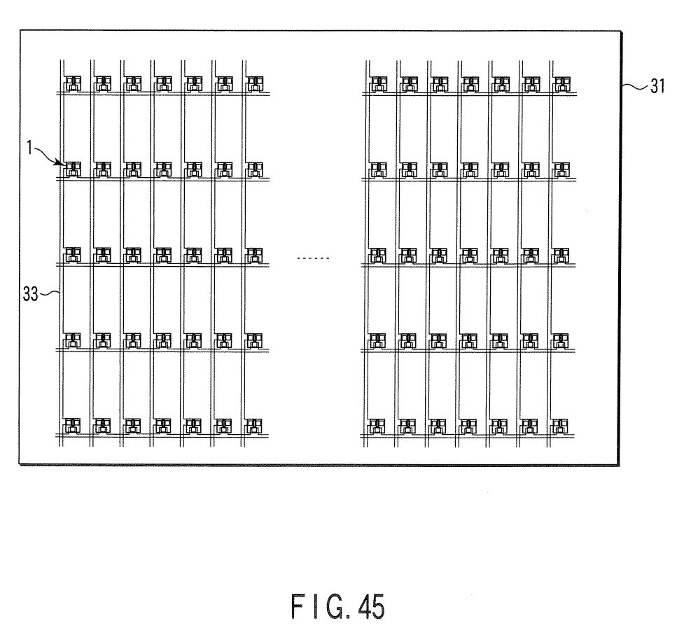

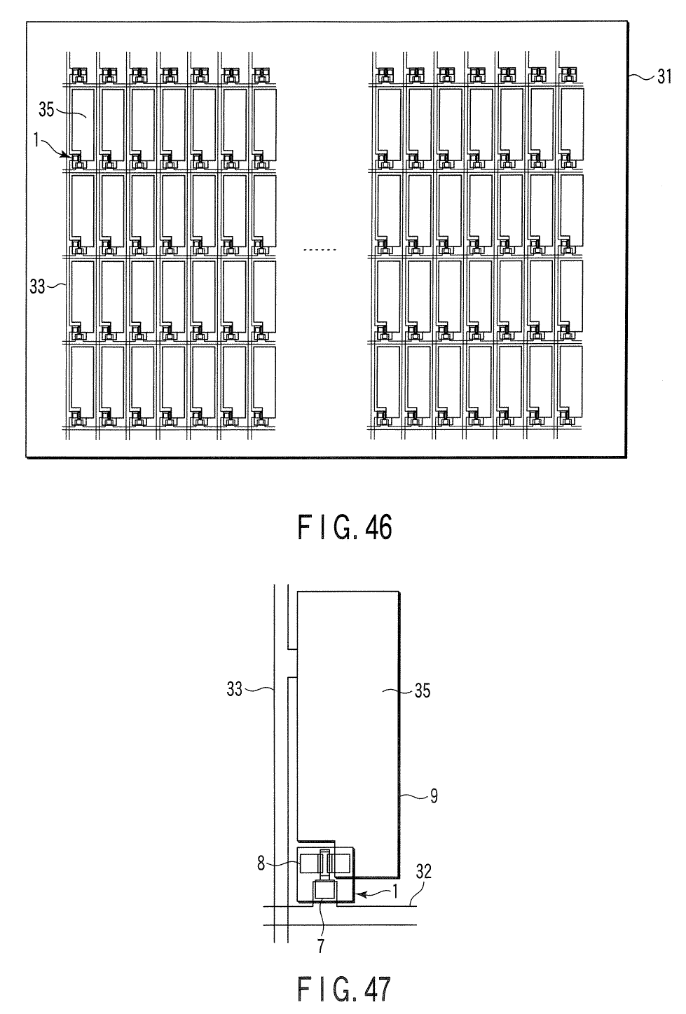

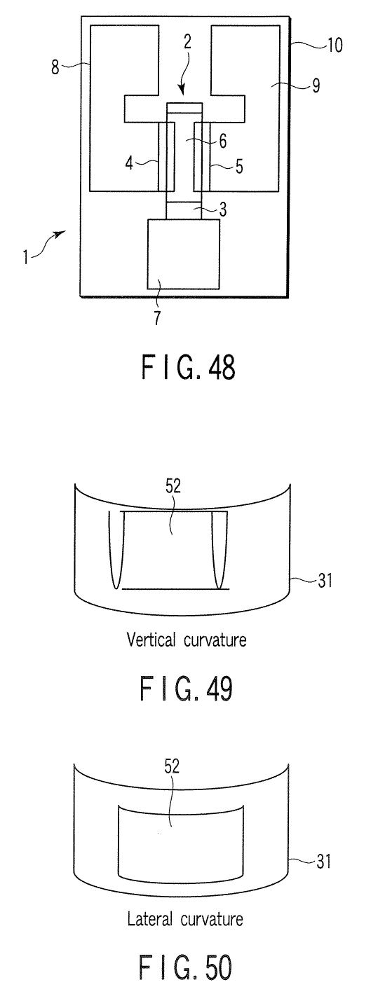

The intermediate transcription substrate 21 after the elements 1 are transcribed from the intermediate transcription substrate 21 to the transcription destination substrate 31, is shown in FIG. 38. The transcription destination substrate 31 after the elements 1 are transcribed from the intermediate transcription substrate 21 to the transcription destination substrate 31, is shown in FIG. 39. As shown in FIG. 38, the elements 1 transcribed to the intermediate transcription substrate 21 are removed and disappeared from the intermediate transcription substrate 21 in a pitch of one per twelve to be transcribed onto the transcription destination substrate 31.

Next, the signal lines 33, the planarizing films 40, and the pixel electrodes 35 are formed on the transcription destination substrate 31 on which the elements 1 have been arranged in a matrix form by the same method as that of the first embodiment. A part of a pixel region including these components is shown in FIG. 40.

An active matrix substrate is formed in accordance with the above processes, and the substrate can be used for manufacturing a TFT-LCD.

In an active matrix substrate obtained by the above method, the peripheral sides of the element 1 form a square, the TFT 2 is arranged in the central area of the element 1, and the elements 1 in which no electrode or semiconductor layer is arranged at one interior corner among the four interior corners of the square are provided in the active matrix substrate. This makes it possible to manufacture an active matrix substrate in which a defect in the TFT 2 due to side etching or permeation of etchant is prevented from occurring.

### Third Embodiment

Next, a third embodiment will be described. In the present embodiment, a flexible substrate such as a plastic film is used as a transcription destination substrate.

A transcription type active matrix substrate is formed by the same method as that of the first embodiment by using a plastic substrate as a transcribing destination substrate. Here, usable examples of the plastic substrate include a plastic film whose specific gravity is about 1.0 to 1.4, and whose thickness is 0.05 to 0.5 mm, such as polycarbonate (PC), polyethylene terephthalate (PET), polyarylate, polyetherimide (PEI), polyether sulphone (PES), polyether-ether-ketone (PEEK), polyimide (PI), polyethylene naphthalate (PEN), and polyolefine. However, it is not limited to the materials enumerated above.

A TFT-LCD manufactured by using a flexible active matrix substrate has been curved with a radius of curvature of 30 mm in a vertical direction in an experiment as shown in FIG. 49. Further, the TFT-LCD has been curved with a radius of curvature of 30 mm in a lateral direction as shown in FIG. 50. In both cases, warps in the channel directions due to the curvatures are made smaller to be about 1/√2 as compared with a warp in the case where it is curved along the channel direction at the same radius of curvature. Deterioration in displayed image quality and cracks in the channel portion due to variations in a transfer property of the TFT have not been brought about, and satisfactory displays have been obtained. In the respective embodiments described above, the peripheral sides of the element 1 form a square. However, it is not limited to a square, and it may be a shape such as a rectangle, a parallelogram, and a rhombus. However, from the standpoint of the manufacturing processes, it is preferably a square or a rectangle.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An element forming substrate comprising:
a substrate; and
a plurality of elements which are arranged in a matrix form on the substrate, each of the elements including a thin film transistor and contact pads connected to the transistor, and having peripheral sides separated from adjacent elements in a plane of the substrate, and a channel direction of the transistor being inclined relative to the peripheral sides of the elements.

2. The element forming substrate according to claim 1, wherein the channel direction of the transistor is inclined at an angle of substantially 45 degrees relative to the peripheral sides of the elements.

3. The element forming substrate according to claim 1, wherein the peripheral sides of the element form a square or a rectangle.

4. The element forming substrate according to claim 2, wherein
the transistor comprises a gate electrode, a semiconductor layer formed on the gate electrode via an insulating film, and a source electrode and a drain electrode which are connected to the semiconductor layer, and
the contact pads comprise a gate electrode contact pad connected to the gate electrode, a source electrode contact pad connected to the source electrode, and a drain electrode contact pad connected to the drain electrode, the source electrode contact pad and the drain electrode contact pad being arranged, among four interior corners including a first interior corner, a second interior corner, a third interior corner and a fourth interior corner configured by the peripheral sides of the element, at the first and second interior corners opposite to each other, the gate electrode contact pad being arranged at the third interior corner which is opposite to the fourth interior corner, and the semiconductor layer being not formed at the fourth interior corner.

5. The element forming substrate according to claim 4, wherein the gate electrode and the gate electrode contact pad are formed of a same layer, the source electrode and the source electrode contact pad are formed of a same layer, and the drain electrode and the drain electrode contact pad are formed of a same layer.

6. An element forming substrate comprising:
a substrate; and
a plurality of elements which are arranged in a matrix form on the substrate, each of the elements including a thin film transistors and contact pads connected to the thin film transistor, a channel direction of the transistor is inclined relative to an array direction of the elements.

7. The element forming substrate according to claim 6, wherein the channel direction of the transistor is inclined at an angle of substantially 45 degrees relative to the array direction of the elements.

8. An active matrix substrate comprising:
a substrate;
a plurality of wirings including gate lines and signal lines which are arranged in a matrix form on the substrate;
a plurality of elements which are arranged in intersection portions of the wirings, each of the elements including a thin film transistor and contact pads connected to the transistor, and having peripheral sides separated from adjacent elements in a plane of the substrate, a channel direction of the thin film transistor is inclined relative to a wiring direction of the wirings.

9. The active matrix substrate according to claim 8, wherein the channel direction of the transistor is inclined at an angle of substantially 45° relative to the wiring direction of the wirings.

10. The active matrix substrate according to claim 8, wherein the peripheral sides of the elements form a square or a rectangle.

11. The active matrix substrate according to claim 10, wherein
the transistor comprises a gate electrode, a semiconductor layer formed on the gate electrode via an insulating film, and a source electrode and a drain electrode which are connected to the semiconductor layer, and
the contact pads comprise a gate electrode contact pad connected to the gate electrode, a source electrode contact pad connected to the source electrode, and a drain electrode contact pad connected to the drain electrode, the source electrode contact pad and the drain electrode contact pad being arranged, among four interior corners including a first interior corner, a second interior corner, a third interior corner and a fourth interior corner configured by the peripheral sides of the element, at the first and second interior corners opposite to each other, the gate electrode contact pad being arranged at the third interior corner which is opposite to the fourth interior corner, and the semiconductor layer being not formed at the fourth interior corner.

12. The active matrix substrate according to claim 11, wherein the gate electrode and the gate electrode contact pad are formed of a same layer, the source electrode and the source electrode contact pad are formed of a same layer, and the drain electrode and the drain electrode contact pad are formed of a same layer.

13. An active matrix substrate comprising:
a substrate;
a plurality of wirings including gate lines and signal lines which are arranged in a matrix form on the substrate; and
a plurality of elements which are arranged in intersection portions of the wirings, each of the elements including a thin film transistor and contact pads connected to the transistor, the transistor comprising a gate electrode, a semiconductor layer formed on the gate electrode via an insulating film, and a source electrode and a drain electrode which are connected to the semiconductor layer, the contact pads comprising a gate electrode contact pad connected to the gate electrode, a source electrode contact pad connected to the source electrode, and a drain electrode contact pad connected to the drain electrode, each of the elements having peripheral sides separated from adjacent elements in a plane of the substrate, the source electrode contact pad and the drain electrode contact pad being arranged, among four interior corners including a first interior corner, a second interior corner, a third interior corner and a fourth interior corner configured by the peripheral sides of the element, at the first and second interior corners opposite to each other, the gate electrode contact pad being arranged at the third interior corner which is opposite to the fourth interior corner, and the semiconductor layer being not formed at the fourth interior corner.

14. The active matrix substrate according to claim 13, wherein the peripheral sides of the element form a square or a rectangle.

15. The active matrix substrate according to claim 13 wherein the gate electrode and the gate electrode contact pad are formed of a same layer, the source electrode and the source electrode contact pad are formed of a same layer, and the drain electrode and the drain electrode contact pad are formed of a same layer.

16. A method of manufacturing an active matrix substrate, comprising:
forming a plurality of elements in a matrix form on an element forming substrate, each of the elements including a thin film transistor and contact pads connected to the transistor;
separating the elements from each other to form peripheral sides of the elements; and
transcribing the separated elements onto a transcription destination substrate;
wherein, when the elements are formed, a channel direction of the thin film transistor is inclined relative to the peripheral sides of the elements.

17. The method according to claim 16, wherein the peripheral sides of the elements form a square or a rectangle.

18. The method according to claim 16, wherein the channel direction of the thin film transistor is inclined at an angle of substantially 45° to the peripheral sides of the elements.

19. The method according to claim 16, wherein the separated elements are transcribed on the transcription destination substrate at a pitch of an integral multiple of a pitch of the elements on the element forming substrate.

20. The method according to claim 16, wherein the separated elements on the element forming substrate are transcribed onto an intermediate transcription substrate, and in turn transcribed from the intermediate transcription substrate onto the transcription destination substrate.
